(19) United States
(12) Patent Application Publication
(10) Pub. No.: US 2022/0325623 A1
(43) Pub. Date: Oct. 13, 2022

(54) ESTIMATIONS OF RESERVOIR PARAMETERS WITH A MULTIPLE-STORAGE PHENOMENON IN DRILL STEM TESTS FOR NO PRODUCTION AT SURFACE

(71) Applicant: SAUDI ARABIAN OIL COMPANY, Dhahran (SA)

(72) Inventor: Noor M. Anisur Rahman, Dhahran (SA)

(73) Assignee: SAUDI ARABIAN OIL COMPANY, Dhahran (SA)

(21) Appl. No.: 17/211,245

(22) Filed: Mar. 24, 2021

(51) Int. Cl. E21B 49/08; E21B 47/06

(52) U.S. Cl. CPC E21B 49/087; E21B 47/06; E21B 2200/20

(57) ABSTRACT

A method of estimating reservoir properties is disclosed. The method includes obtaining downhole pressure data during a drill stem test in a wellbore penetrating a reservoir, computing a first linearity measure of a first diagnostic plot, wherein the first diagnostic plot represents a first dependency of the downhole pressure data on a linear-scale with respect to inverse time on a linear-scale, determining, based at least on the first linearity measure, data sufficiency of the drill stem test, and generating, from the downhole pressure data and based at least on the data sufficiency, an estimation of the reservoir properties.

### BACKGROUND

Drill stem test is an oil and gas exploration procedure to isolate, stimulate and flow a subterranean formation to determine the fluids present and the rate at which they can be produced. Drill stem tests are performed to evaluate the economic potential of completing the formation drilling by identifying productive capacity, pressure, permeability or extent of an oil or gas reservoir. Drill stem tests are performed by deploying a series of tools known as a test bottomhole assembly (BHA). A basic drill stem test BHA includes a packer or packers, which act as an expanding plug to be used to isolate sections of the well for the testing process, valves that may be opened or closed from the surface during the test, and recorders used to document pressure during the test. In addition to packers, a downhole valve is used to open and close the formation to measure reservoir characteristics such as pressure and temperature which are charted on downhole recorders within the BHA.

### SUMMARY

In general, in one aspect, the invention relates to a method of estimating reservoir properties. The method includes obtaining downhole pressure data during a drill stem test in a wellbore penetrating a reservoir, computing a first linearity measure of a first diagnostic plot, wherein the first diagnostic plot represents a first dependency of the downhole pressure data on a linear-scale with respect to inverse time on a linear-scale, determining, based at least on the first linearity measure, data sufficiency of the drill stem test, and generating, from the downhole pressure data and based at least on the data sufficiency, an estimation of the reservoir properties.

In general, in one aspect, the invention relates to a system for estimating reservoir properties. The system includes a memory, and a computer processor connected to the memory and that obtains downhole pressure data during a drill stem test in a wellbore penetrating a reservoir, computes a first linearity measure of a first diagnostic plot, wherein the first diagnostic plot represents a first dependency of the downhole pressure data on a linear-scale with respect to inverse time on a linear-scale, determines, based at least on the first linearity measure, data sufficiency of the drill stem test, and generates, from the downhole pressure data and based at least on the data sufficiency, an estimation of the reservoir properties.

In general, in one aspect, the invention relates to a non-transitory computer readable medium (CRM) storing computer readable program code for estimating reservoir properties. The computer readable program code, when executed by a computer, includes functionality for obtaining downhole pressure data during a drill stem test in a wellbore penetrating a reservoir, computing a first linearity measure of a first diagnostic plot, wherein the first diagnostic plot represents a first dependency of the downhole pressure data on a linear-scale with respect to inverse time on a linear-scale, determining, based at least on the first linearity measure, data sufficiency of the drill stem test, and generating, from the downhole pressure data and based at least on the data sufficiency, an estimation of the reservoir properties.

Other aspects and advantages will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1A-1C show systems in accordance with one or more embodiments.

FIG. 2 shows a flowchart in accordance with one or more embodiments.

FIGS. 3A-3F show an example in accordance with one or more embodiments.

FIGS. 4A and 4B show a computing system in accordance with one or more embodiments.

### DETAILED DESCRIPTION

Specific embodiments of the disclosure will now be described in detail with reference to the accompanying figures. Like elements in the various figures are denoted by like reference numerals for consistency.

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Embodiments of the invention provide a method, a system, and a non-transitory computer readable medium for estimating reservoir properties with a multiple-storage phenomenon in drill stem tests. In one or more embodiments of the invention, downhole pressure data is obtained during a drill stem test in a wellbore penetrating a reservoir where there is no production fluid flow at the surface. The downhole pressure data is used to generate a first diagnostic plot representing a first dependency of the downhole pressure data on a linear-scale with respect to inverse time on a linear-scale, and a second diagnostic plot representing a second dependency of an impulse derivative of the downhole pressure data on the log-scale with respect to time on the log-scale. A first and second linearity measures of the first and second diagnostic plots are computed based on the downhole wellbore pressure and used to determine data sufficiency of the drill stem test. Accordingly, an estimation of the reservoir properties is generated from the downhole pressure data based at least on the data sufficiency.

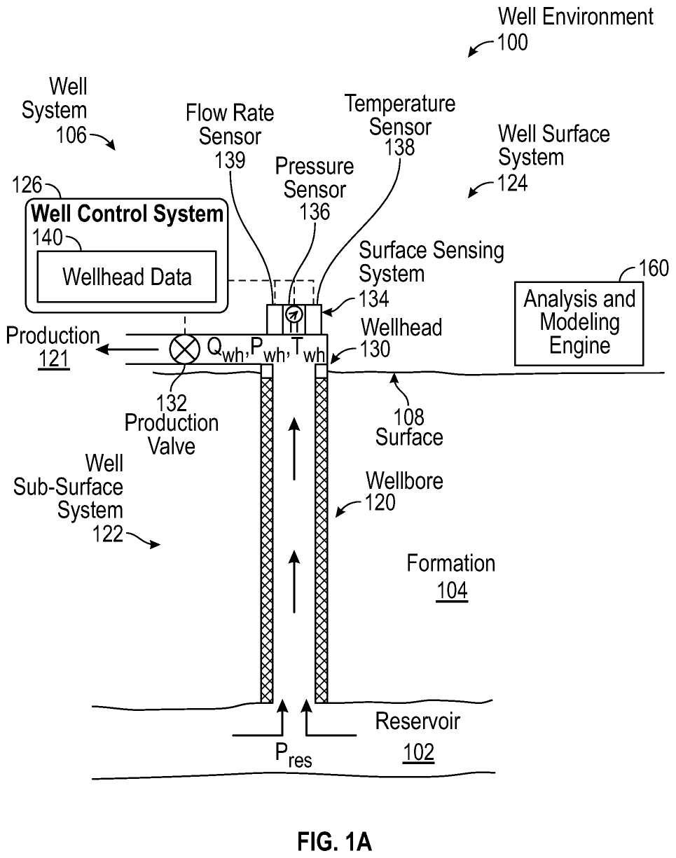

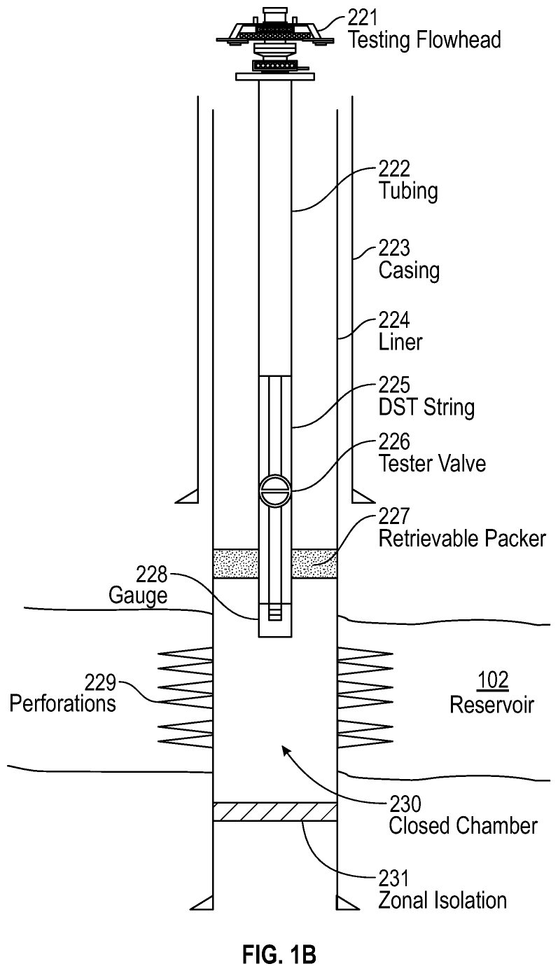

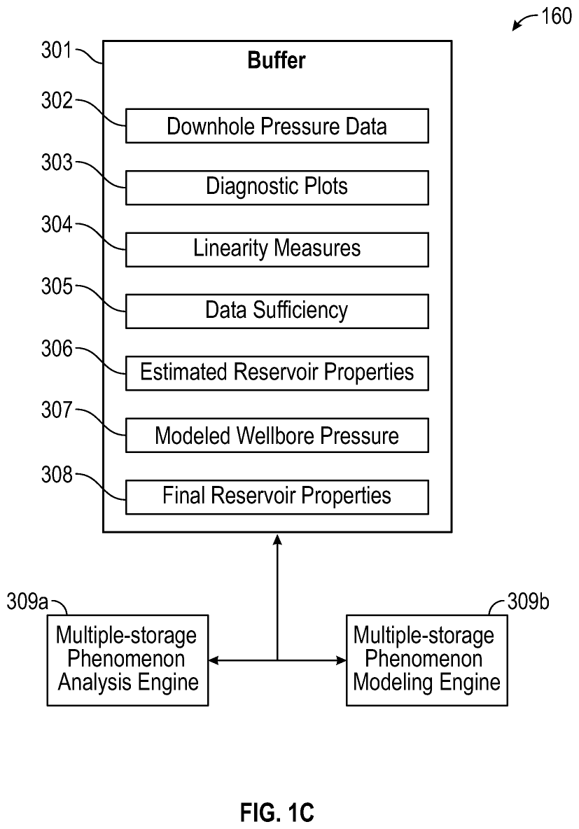

FIG. 1A shows a schematic diagram in accordance with one or more embodiments. More specifically, FIG. 1A illustrates a well environment (100) that includes a hydrocarbon reservoir (“reservoir”) (102) located in a subsurface formation (“formation”) (104) and a well system (106). The formation (104) may include a porous formation that resides underground, beneath the Earth's surface (“surface”) (108). In the case of the well system (106) being a hydrocarbon well, the reservoir (102) may include a portion of the formation (104). The formation (104) and the reservoir (102) may include different layers of rock having varying characteristics, such as varying degrees of permeability, porosity, capillary pressure, and resistivity. In the case of the well system (106) being operated as a production well, the well system (106) may facilitate the extraction of hydrocarbons (or “production”) from the reservoir (102).

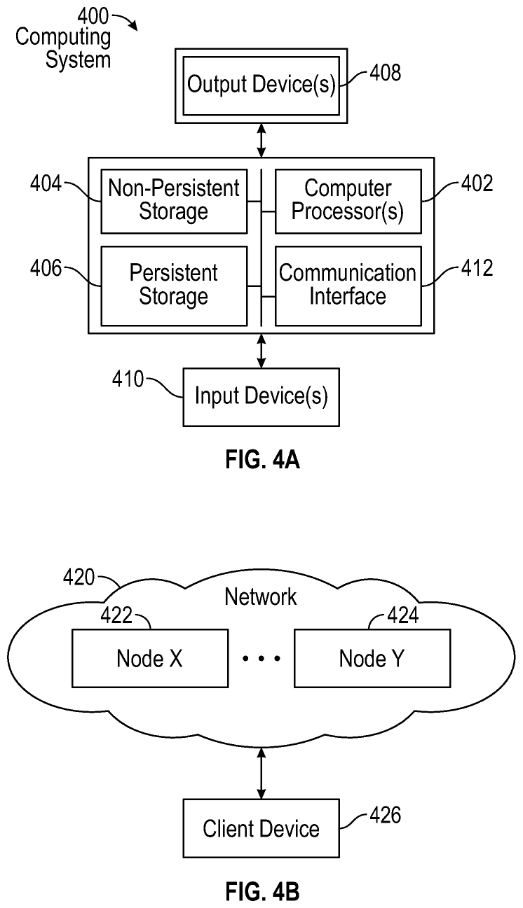

In some embodiments, the well system (106) includes a wellbore (120), a well sub-surface system (122), a well surface system (124), and a well control system (“control system”) (126). The control system (126) may control various operations of the well system (106), such as well production operations, well completion operations, well maintenance operations, and reservoir monitoring, assessment and development operations. In some embodiments, the control system (126) includes a computer system that is the same as or similar to that of computer system (400) described below in FIGS. 4A and 4B and the accompanying description.

The wellbore (120) may include a bored hole that extends from the surface (108) into a target zone of the formation (104), such as the reservoir (102). An upper end of the wellbore (120), terminating at or near the surface (108), may be referred to as the “up-hole” end of the wellbore (120), and a lower end of the wellbore, terminating in the formation (104), may be referred to as the “down-hole” end of the wellbore (120). The wellbore (120) may facilitate the circulation of drilling fluids during drilling operations, the flow of hydrocarbon production (“production”) (121) (e.g., oil and gas) from the reservoir (102) to the surface (108) during production operations, the injection of substances (e.g., water) into the formation (104) or the reservoir (102) during injection operations, or the communication of monitoring devices (e.g., logging tools) into the formation (104) or the reservoir (102) during monitoring operations (e.g., during in situ logging operations).

In some embodiments, during operation of the well system (106), the control system (126) collects and records wellhead data (140) for the well system (106). The wellhead data (140) may include, for example, a record of measurements of wellhead pressure (P_{wh}) (e.g., including flowing wellhead pressure), wellhead temperature (T_{wh}) (e.g., including flowing wellhead temperature), wellhead production rate (Q_{wh}) over some or all of the life of the well (106), and water cut data. In some embodiments, the measurements are recorded in real-time, and are available for review or use within seconds, minutes, or hours of the condition being sensed (e.g., the measurements are available within 1 hour of the condition being sensed). In such an embodiment, the wellhead data (140) may be referred to as “real-time” wellhead data (140). Real-time wellhead data (140) may enable an operator of the well (106) to assess a relatively current state of the well system (106), and make real-time decisions regarding development of the well system (106) and the reservoir (102), such as on-demand adjustments in regulation of production flow from the well.

In some embodiments, the well sub-surface system (122) includes casing installed in the wellbore (120). For example, the wellbore (120) may have a cased portion and an uncased (or “open-hole”) portion. The cased portion may include a portion of the wellbore having casing (e.g., casing pipe and casing cement) disposed therein. The uncased portion may include a portion of the wellbore not having casing disposed therein. In embodiments having a casing, the casing defines a central passage that provides a conduit for the transport of tools and substances through the wellbore (120). For example, the central passage may provide a conduit for lowering logging tools into the wellbore (120), a conduit for the flow of production (121) (e.g., oil and gas) from the reservoir (102) to the surface (108), or a conduit for the flow of injection substances (e.g., water) from the surface (108) into the formation (104). In some embodiments, the well sub-surface system (122) includes production tubing installed in the wellbore (120). The production tubing may provide a conduit for the transport of tools and substances through the wellbore (120). The production tubing may, for example, be disposed inside casing. In such an embodiment, the production tubing may provide a conduit for some or all of the production (121) (e.g., oil and gas) passing through the wellbore (120) and the casing.

In some embodiments, the well surface system (124) includes a wellhead (130). The wellhead (130) may include a rigid structure installed at the “up-hole” end of the wellbore (120), at or near where the wellbore (120) terminates at the Earth's surface (108). The wellhead (130) may include structures (called “wellhead casing hanger” for casing and “tubing hanger” for production tubing) for supporting (or “hanging”) casing and production tubing extending into the wellbore (120). Production (121) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (120). For example, the well surface system (124) may include one or more production valves (132) that are operable to control the flow of production (121). For example, a production valve (132) may be fully opened to enable unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

In some embodiments, the wellhead (130) includes a choke assembly. For example, the choke assembly may include hardware with functionality for opening and closing the fluid flow through pipes in the well system (106). Likewise, the choke assembly may include a pipe manifold that may lower the pressure of fluid traversing the wellhead. As such, the choke assembly may include set of high pressure valves and at least two chokes. These chokes may be fixed or adjustable or a mix of both. Redundancy may be provided so that if one choke has to be taken out of service, the flow can be directed through another choke. In some embodiments, pressure valves and chokes are communicatively coupled to the well control system (126). Accordingly, a well control system (126) may obtain wellhead data regarding the choke assembly as well as transmit one or more commands to components within the choke assembly in order to adjust one or more choke assembly parameters.

Keeping with FIG. 1A, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120).

In some embodiments, the surface sensing system (134) includes a surface pressure sensor (136) operable to sense the pressure of production (121) flowing through the well surface system (124), after it exits the wellbore (120). The surface pressure sensor (136) may include, for example, a wellhead pressure sensor that senses a pressure of production (121) flowing through or otherwise located in the wellhead (130). In some embodiments, the surface sensing system (134) includes a surface temperature sensor (138) operable to sense the temperature of production (121) flowing through the well surface system (124), after it exits the wellbore (120). The surface temperature sensor (138) may include, for example, a wellhead temperature sensor that senses a temperature of production (121) flowing through or otherwise located in the wellhead (130), referred to as “wellhead temperature” (T_{wh}). In some embodiments, the surface sensing system (134) includes a flow rate sensor (139) operable to sense the flow rate of production (121) flowing through the well surface system (124), after it exits the wellbore (120). The flow rate sensor (139) may include hardware that senses a flow rate of production (121) (Q_{wh}) passing through the wellhead (130).

In some embodiments, the well surface system (124) includes tools for performing drill stem test (DST) described in reference to FIG. 1B below. The well system (106) further includes an analysis and modeling engine (160). For example, the analysis and modeling engine (160) may include hardware and/or software with functionality for simulating and modeling DST data to generate input for reservoir simulations. The analysis and modeling engine (160) may further include functionality for performing the reservoir simulations using such input. While the analysis and modeling engine (160) is shown at a well site, embodiments are contemplated where reservoir and/or basin simulators are located away from well sites. In one or more embodiments of the invention, the analysis and modeling engine (160) may include a computer system that is similar to the computer system (400) described below with regard to FIGS. 4A and 4B and the accompanying description.

Turning to FIG. 1B, FIG. 1B shows a schematic diagram in accordance with one or more embodiments. Specifically, FIG. 1B illustrates details of the well system (106) depicted in FIG. 1A above for performing the drill stem test (DST). In one or more embodiments, one or more of the modules and/or elements shown in FIG. 1B may be omitted, repeated, and/or substituted. Accordingly, embodiments of the invention should not be considered limited to the specific arrangements of modules and/or elements shown in FIG. 1B.

As shown in FIG. 1B, the testing flowhead (221), casing (223), liner (224), and perforations (229) are part of the wellhead (130) and wellbore (120) depicted in FIG. 1A above. In one or more embodiments of the invention, the tubing (222) and DST string (225) are used to deploy a DST tool into the wellbore (120) to perform the DST. The DST tool includes the tester valve (226), gauge (228), and packers (i.e., retrievable packer (227), zonal isolation (231)). The DST is performed to determine the productive capacity, pressure, permeability, or extent of the hydrocarbon reservoir (102) depicted in FIG. 1A above. The DST tool is used to isolate the zone of interest (e.g., closed chamber (230)) with temporary packers. Next, one or more valves are opened to allow the reservoir fluids to flow through the DST string (225) and tubing (222) for a time period. Data obtained from the DST include one or more of fluid samples, reservoir pressure, formation properties (e.g., permeability, skin, and radius of investigation), flow rate, etc. After the DST, the operator closes the valves, removes the packers, and trips the DST bottomhole assembly out of the wellbore (120).

In one or more embodiments, the DST is performed during the drilling phase of the wellbore (120). A determination may be made to complete the drilling and completion of the wellbore (120) if the data obtained from the DST confirms that the productive capacity, pressure, permeability or extent of the reservoir (102) meet certain economic criteria. Otherwise, the drilling and completion of the wellbore (120) may be abandoned if the data obtained from the DST indicates that the productive capacity, pressure, permeability or extent of the reservoir (102) do not meet the economic criteria.

More specifically, the DST can be viewed as a temporary completion of the wellbore (120). The DST tool is run into the mud-filled wellbore (120) in order to isolate the interval of interest (e.g., closed chamber (230)) from the surrounding zones, and a sequence of alternating production and shut-in phases is performed as a transient well test. The bottomhole pressure is continuously recorded by the gauge (228) as the DST starts with the opening of the bottom-hole tester valve (226), allowing the formation fluids to enter into the drill string (i.e., DST string (225), tubing (222)), which may be empty or partially filled with a liquid cushion. In some cases, the drill string may also contain pressurized gas. The first flow period is usually short, and the produced fluids do not reach the surface by the time of the shut-in of the wellbore (120). However, after the wellbore (120) is shut-in, a pressure recovery takes place in the reservoir (102), due to the fluid withdrawal during the production phase. Analysis of pressure-time data (also referred to as transient-pressure data) obtained during the transient well test, in combination with the fluid production or injection rates, and the rock and fluid properties, provides the initial reservoir pressure, and an estimate of the formation permeability and wellbore condition.

When a producing well is shut-in at surface, flow into the wellbore (120) at sandface (i.e., through perforations (229) or other interfaces between the wellbore (120) and the reservoir (102)) continues after shut-in. This type of flow regime is referred to as afterflow or wellbore storage. Wellbore storage effects are associated with a continuously varying flow rate into the closed chamber from the formation and is characterized using a wellbore storage constant, denoted as CS, where CS=VWS×CWS, VWS=volume of the closed chamber at a given time, and CWS=compressibility of the wellbore fluid evaluated at the mean wellbore pressure and temperature. Other methods may also be used for estimating the CS values.

Even outside of the shut-in phase, there are various reasons no production of reservoir fluid flows at the surface during the test. There are situations when the measured downhole pressures are dominated by the wellbore storage phenomenon and the produced reservoir fluids may not get produced at surface. Moreover, the initial production from the reservoir to the wellbore is facilitated by the wellbore storage phenomenon. Yet the downhole data can be useful in estimating the reservoir properties regardless of any production to the surface. When the reservoir has the reasonable permeability, the dominance of the storage phenomenon can subside with time, and the measured pressures directly reflect the reservoir responses due to natural flow of reservoir fluids to surface.

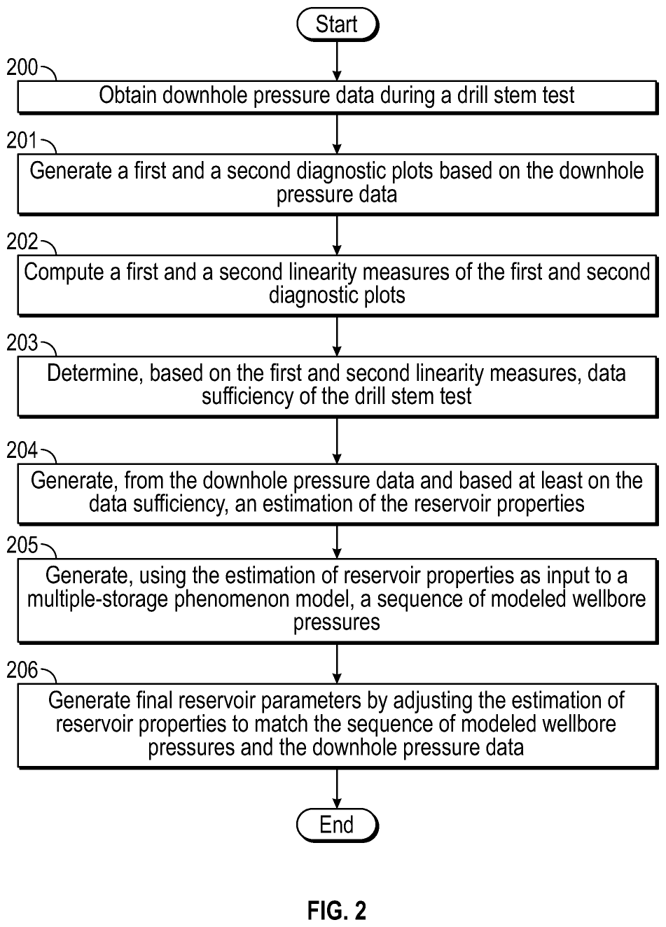

Returning to the discussion of FIG. 1B, a single closed chamber (230) is considered for simplicity. Volume changes in the closed chamber (230) can be caused by a sequence of operating different valves that allow or restrict fluid influx into the closed chamber (230) over time. Chamber volume, type of fluid and fluid movement along the drill pipe at a given time dictate the value of wellbore storage constant at that time. A procedure of analyzing and modeling the downhole data with arbitrary number of wellbore storage constants and no production of reservoir fluids at surface during a transient well test is described in reference to FIG. 2 below.

Turning to FIG. 1C, FIG. 1C shows a schematic diagram in accordance with one or more embodiments. Specifically, FIG. 1C illustrates details of the analysis engine (106) depicted in FIG. 1A above. In one or more embodiments, one or more of the modules and/or elements shown in FIG. 1C may be omitted, repeated, and/or substituted. Accordingly, embodiments of the invention should not be considered limited to the specific arrangements of modules and/or elements shown in FIG. 1C.

As shown in FIG. 1C, the analysis and modeling engine (160) has multiple components, including, for example, a buffer (301), a multiple-storage phenomenon analysis engine (309a), and a multiple-storage phenomenon modeling engine (309b). Each of these components (301, 309a, 309b) may be implemented in hardware (i.e., circuitry), software, or any combination thereof. Further, each of these components (301, 309a, 309b) may be located on the same computing device (e.g., personal computer (PC), laptop, tablet PC, smart phone, multifunction printer, kiosk, server, etc.) or on different computing devices connected by a network of any size having wired and/or wireless segments. In one or more embodiments, these components may be implemented using the computing system (400) described below in reference to FIGS. 4A and 4B. Each of these components is discussed below.

In one or more embodiments of the invention, the buffer (301) is configured to store downhole pressure data (302), diagnostic plots (303), linearity measures (304), data sufficiency (305), estimated reservoir properties (306), modeled wellbore pressure (307), and final reservoir properties (308). The downhole pressure data (302) is pressure measurement data captured during a drill stem test and using downhole gauges, such as gauge (228) depicted in FIG. 1B above. The diagnostic plots (303) are data plots of the downhole pressure data (302) and related/derived information of the downhole pressure data (302) with respect to the elapsed time or inverse elapsed time during the drill stem test. The diagnostic plots (303) may be based on linear and/or logarithmic scales for one or more of the plotting coordinates. More specifically, the diagnostic plots (303) are a collection of data value pairs where each data value pair includes a first data value and a second data value. The first data value corresponds to a pressure data entry or related/derived information in the downhole pressure data (302). The second data value corresponds to the elapsed time or inverse elapsed time corresponding to the first data value. As noted above, the first data value and the second data value may be based on linear and/or logarithmic scales. In an example scenario, the collection of data value pairs of the diagnostic plots (303) is displayed as curves to be viewed by a user for visual analysis. In another example scenario, the collection of data value pairs of the diagnostic plots (303) are automatically analyzed by the multiple-storage phenomenon analysis engine (309a) to generate the linearity measures (304), data sufficiency (305), and estimated reservoir properties (306). The multiple-storage phenomenon analysis engine (309a) analyzes the collection of data value pairs of the diagnostic plots (303) based on adjustable parameters including wellbore storage constants described above and other reservoir parameters such as reservoir transmissibility. The adjustable parameters are adjusted to match modeled results in the modeling step performed by the multiple-storage phenomenon modeling engine (309b).

Continuing the discussion of the data stored in the buffer (301), the linearity measures (304) are respective measures of the diagnostic plots (303) that represent how close a portion of the diagnostic plots (303) can be approximated by a straight line. In particular, the linearity measures (304), when exceeding a predetermined threshold, indicates that the duration of the drill stem test is sufficiently long such that the downhole pressure data (302) is sufficiently complete to generate approximate reservoir properties. The data sufficiency (305) is a measure of how sufficient the downhole pressure data (302) is to generate approximate reservoir properties. The estimated reservoir properties (306) are the approximate values of reservoir parameters that are generated from the downhole pressure data (302). The modeled wellbore pressure (307) are computed wellbore pressure values using the estimated reservoir properties (306) as input to a computer model. As noted above, the adjustable parameters (e.g., wellbore storage constants, reservoir transmissibility) are adjusted to match the modeled wellbore pressure (307) with the downhole pressure data (302) throughout the elapsed time of the drill stem test. The values of the adjustable parameters that result in the best match are referred to as the best-match parameter values and are used by the multiple-storage phenomenon analysis engine (309a) to generate the final reservoir properties (308). In other words, the final reservoir properties (308) equal the estimated reservoir properties (306) when the best-match parameter values are used by the multiple-storage phenomenon analysis engine (309a) to analyze the diagnostic plots (303).

As noted above, the multiple-storage phenomenon analysis engine (309a) is configured to generate the diagnostic plots (303) from the downhole pressure data (302), and to analyze the diagnostic plots (303) to generate the linearity measures (304), data sufficiency (305), and estimated reservoir properties (306). The multiple-storage phenomenon modeling engine (309b) is configured to generate the modeled wellbore pressure (307) using the estimated reservoir properties (306) as input to a computer model, referred to as the multiple-storage phenomenon model. The multiple-storage phenomenon modeling engine (309b) is further configured to adjust the adjustable parameters to achieve a best match between the modeled wellbore pressure (307) and the downhole pressure data (302) throughout the elapsed time of the drill stem test.

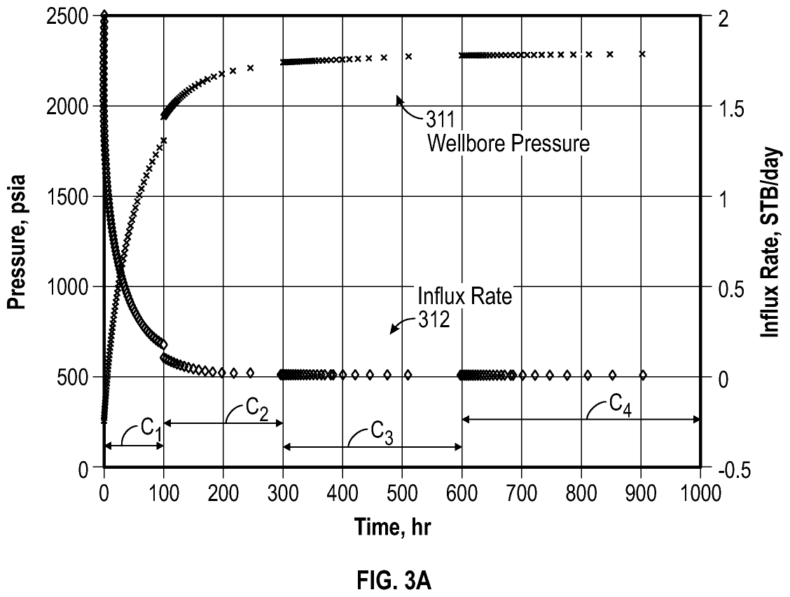

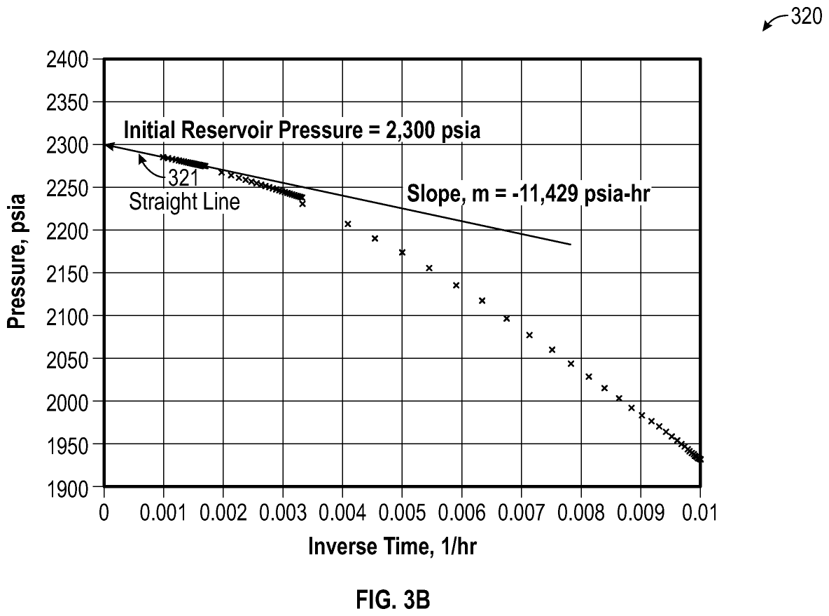

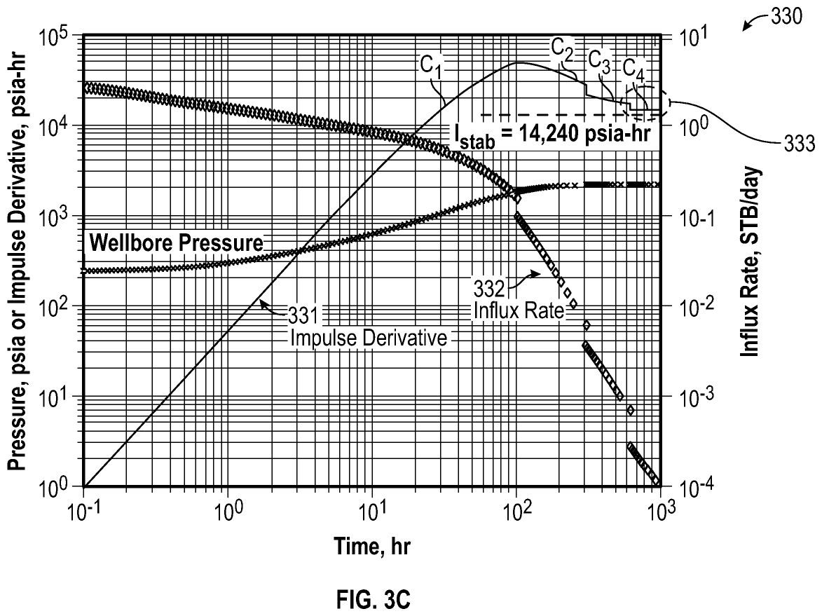

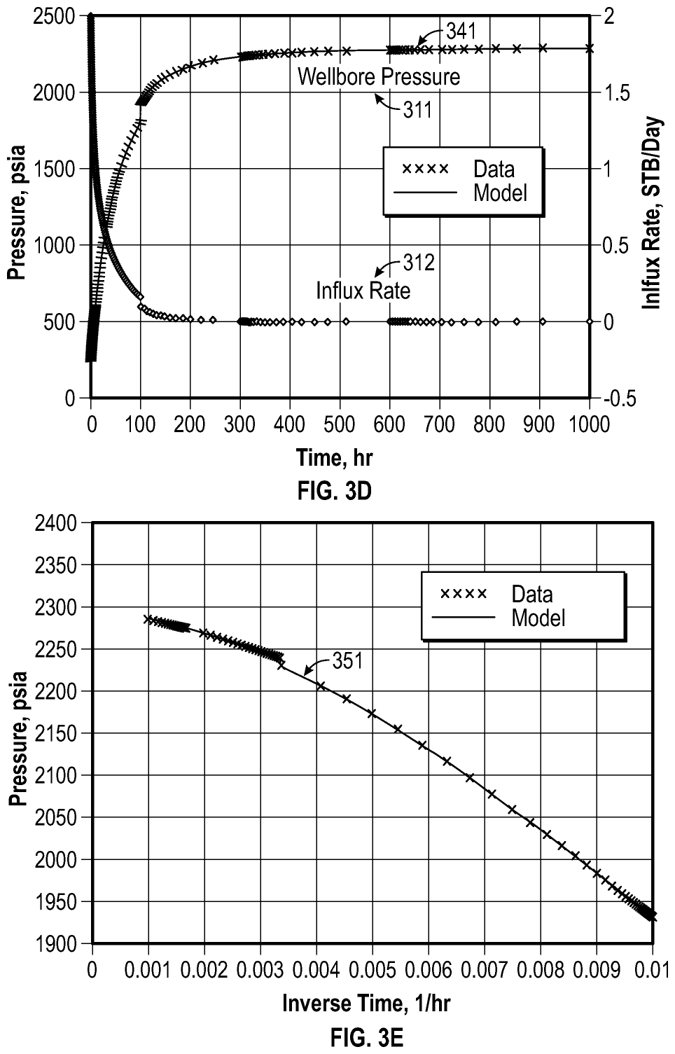

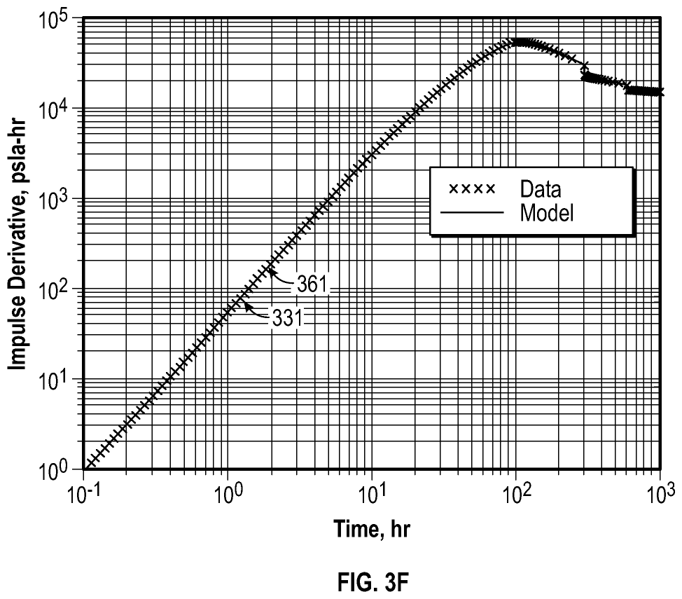

In one or more embodiments, the multiple-storage phenomenon analysis engine (309a) and the multiple-storage phenomenon modeling engine (309b) perform the functions described above using the method described in reference to FIG. 2 and the workflow steps listed in TABLES 2 and 4 below. An example of estimating the reservoir properties with a multiple-storage phenomenon in drill stem tests where there is no production fluid flow at the surface is described in reference to FIGS. 3A-3F below.

Although the analysis and modeling engine (160) is shown as having four components (301, 309a, 309b), in one or more embodiments of the invention, the analysis and modeling engine (160) may have more or fewer components. Furthermore, the functions of each component described above may be split across components. Further still, each component (301, 309a, 309b) may be utilized multiple times to carry out an iterative operation.

FIG. 2 shows a flowchart in accordance with one or more embodiments. One or more blocks in FIG. 2 may be performed using one or more components as described in FIGS. 1A-1C. While the various blocks in FIG. 2 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

Initially in Block 200, downhole pressure data is obtained during a drill stem test in a wellbore. In one or more embodiments of the invention, the drill stem test includes a multiple-storage phenomenon with no production fluid flow at surface, and the downhole pressure data includes a sequence of terminal wellbore pressures of the multiple-storage phenomenon. In one or more embodiments, the drill stem test continues until at least the data sufficiency satisfies a pre-determined criterion such that the downhole pressure data is sufficiently complete to generate reliable estimation of reservoir properties.

In Block 201, the downhole pressure data is used to generate a first diagnostic plot representing a first dependency of the downhole pressure data on a linear-scale with respect to inverse time on a linear-scale. The inverse time corresponds to one over the elapsed time of the drill stem test. The downhole pressure data is further used to generate a second diagnostic plot representing a second dependency of an impulse derivative of the downhole pressure data on the log-scale with respect to time on the log-scale. The time corresponds to the elapsed time of the drill stem test.

In Block 202, a first and second linearity measures of the first and second diagnostic plots are computed based on the downhole wellbore pressure. The first linearity measure includes a linear regression error of the downhole pressure data with respect to a first straight line on the first diagnostic plot. The second linearity measure includes a linear regression error of the downhole pressure data with respect to a second straight line on the second diagnostic plot, where the second straight line corresponds to a stabilized value of the impulse derivative.

In Block 203, data sufficiency of the drill stem test is determined based on the first linearity measure and the second linearity measure. For example, the data sufficiency may be a combination (e.g., an additional sum, a multiplication product, or other mathematical combination) of the first linearity measure and the second linearity measure.

In Block 204, generating, from the downhole pressure data and based at least on the data sufficiency, an estimation of the reservoir properties. When the drill stem test has run sufficiently long such that the data sufficiency exceeds a predetermined threshold, the downhole pressure data is analyzed to generate the estimated reservoir properties, such as one or more of an estimated initial wellbore pressure, a stabilized value of an impulse derivative of the downhole pressure data, an estimated reservoir transmissibility, and a sequence of estimated wellbore storage constants corresponding to the sequence of terminal wellbore pressures. In particular, one or more of estimated reservoir properties are generated based on one or more of a slope and an abscissa intercept of the first straight line extracted from the first diagnostic plot and the stabilized value of the impulse derivative extracted from the second diagnostic plot.

In Block 205, a sequence of modeled wellbore pressure is generated using the estimation of reservoir properties as input to a multiple-storage phenomenon model. In particular, the multiple-storage phenomenon model represents the mathematical relationship of the wellbore pressure and the estimated reservoir properties.

In Block 206, the final reservoir parameters is generated by adjusting the estimation of reservoir properties to match the sequence of modeled wellbore pressure and the downhole pressure data. In particular, the estimation of reservoir properties include adjustable parameters such as wellbore storage constants, reservoir transmissibility, etc. described above.

FIGS. 3A-3F show an example in accordance with one or more embodiments. The example shown in FIGS. 3A-3F is based on the system and method described in reference to FIGS. 1A-1C and 2 above.

From time to time, reservoir potential may be overlooked prematurely due to a lack of a credible method to analyze the gathered data during drill stem test (DST) without any fluid production at surface. Sometimes fluids are not produced at surface due to reservoir tightness, skin damage, low reservoir pressure or a combination of these factors. The example described below treats such situations as a multiple storage phenomenon for the sake of generality, and provides a method for analyzing and modeling the data for an accurate interpretation. Data sufficiency within the test duration is determined through a systematic process of displaying/analyzing the data on specialized plots. Reservoir transmissibility, flow capacity or permeability, skin factor and reservoir pressure can be extracted as output with certainty by identifying characteristics shapes of specialized plots. These extracted reservoir parameters demonstrate a complete picture of the reservoir potential.

The example described below also estimates the corresponding influx rates from the reservoir to the wellbore under the influence of the changing wellbore storage constants. Note that the effective wellbore volume connected to the reservoir, also known as the chamber volume, at a given time dictates the resultant wellbore storage constant. FIG. 3A shows an example of wellbore pressure profile (311) and influx rate profile (312) for four different sequential wellbore storage constants (i.e., C₁, C₂, C₃, C₄) due to corresponding distinct chamber volumes that are active over different time periods. Each time period, starting from 0 hr, 100 hr, 300 hr, and 600 hr, respectively, corresponds to a distinct progression of wellbore pressure, influx rates with respect to time. In particular, C₁ corresponds to a time period length of 100 hr, C₂ corresponds to a time period length of 200 hr, C₃ corresponds to a time period length of 300 hr, and C₄ corresponds to a time period length of 400 hr.

In an example scenario of FIG. 1B, a vertical well is subject to multiple storage constants over a sequence of time periods without any production at the surface. During these time periods, wellbore storage allows some fluid influx into the well causing transient pressure responses. The downhole gauges (e.g., gauge (228)) capture these pressure responses with time. A method for analyzing and modeling the captured data to extract reservoir parameters indicative of the reservoir potential is described below. Initially, a mathematical model for transient pressure, influx rate and impulse derivative is developed by considering a reservoir system with a vertical well intersecting the entire pay thickness of the reservoir. The well is subject to n distinct wellbore storage constants, C₁, C₂, C₃, . . . , Cₙ in a known time sequence over the test period. Depending upon the magnitude of a storage constant and the initial conditions at the reservoir and at the wellbore, the influx of reservoir fluid into the wellbore controls the pressure and influx rate profiles for a given reservoir. The mathematical model (i.e., multiple-storage phenomenon model) is based on time-dependent wellbore storage constants with no production through the wellbore. The flow of fluid from the reservoir is limited to the influx into the chamber volume within the wellbore. In the mathematical model, the pressure distribution in the reservoir is tied to the inner and outer boundary conditions. The inner boundary condition, at the sandface of a vertical well, accounts for the time-dependent wellbore storage constants. A simplified reservoir with infinite extent in the radial direction is considered for illustration. Modeled solutions for other reservoir geometry can be developed by varying the inner and outer boundary conditions.

The conditions in the reservoir and in the wellbore at Δt=0 is referred to as the initial condition. For example, a constant and uniform pressure, p₀, throughout the reservoir at Δt=0 is defined as the initial condition of the reservoir. In addition, the cushion pressure, p_{wf0}, at Δt=0 is defined as the initial condition at the wellbore.

The mathematical model evaluates the sandface pressures at the equivalent wellbore radius due to the presence of the skin factor. The effective wellbore radius can deal with both positive and negative values of the skin factors. Also, the sandface pressure at the effective wellbore radius is regarded as the flowing wellbore pressure.

Laplace transform technique is used to solve the diffusivity equation along with initial and boundary conditions, resulting in solutions in the Laplace domain. Note that all the equations and examples throughout this disclosure are based on the system of US Oilfield units according to the nomenclature listed in TABLE 1 below. The equations and solutions are described in three separate sections (i.e., pressure computation, influx rate computation, and impulse derivative computation) below.

TABLE 1
Nomenclature

| | |
|---|---|
| B | Formation volume factor of fluid, bbl/STB |
| C₁ | Wellbore storage constant during 1st period, bbl/psia |
| C₂ | Wellbore storage constant during 2nd period, bbl/psia |
| C₃ | Wellbore storage constant during 3rd period, bbl/psia |
| Cₙ | Wellbore storage constant during nth period, bbl/psia |
| cₜ | Total system compressibility, 1/psia |
| h | Pay thickness, ft |
| I(Δt) | Impulse derivative as a function of time, psia-hr |
| I_{stab} | Stabilized value of impulse derivative, psia-hr |
| k | Reservoir permeability, md |
| kh | Reservoir flow capacity, md-ft |
| $\frac{kh}{μ}$ | Reservoir transmissibility, md-ft/cp |
| L | Laplace transform of a time-dependent function (e.g., of p_{wf}) |
| L⁻¹ | Inverse Laplace transform of an already transformed function |
| m | Slope of extrapolated line on p_{wf} versus 1/Δt plot (negative value), psia-hr |
| n | Number of wellbore storage constants in known sequence |
| p₀ | Initial reservoir pressure (static reservoir pressure at Δt = 0), psia |
| p_{wf} | Wellbore flowing pressure at Δt, psia |
| p_{wf0} | Terminal wellbore pressure at Δt = 0 (at the beginning of period due to C₁), psia |
| p_{wf1} | Terminal wellbore pressure at the end of period due to C₁, psia |
| p_{wf2} | Terminal wellbore pressure at the end of period due to C₂, psia |
| p_{wf3} | Terminal wellbore pressure at the end of period due to C₃, psia |
| p_{wf n-1} | Terminal wellbore pressure at the beginning of period due to Cₙ, psia |
| p̅_{wf} | Wellbore flowing pressure in Laplace domain (Laplace transformed), psia-hr |
| q | Rate of production in standard conditions from wellbore, STB/d |
| q̅ | Rate of production in Laplace domain (Laplace transformed), STB-hr/d |
| r | Radial distance in the reservoir from center of well, ft |
| r_{w} | Actual wellbore radius, ft |
| r_{wa} | Apparent wellbore radius, r_{w} exp (−s), ft |
| l | Laplace transform parameter, hr⁻¹ |
| s | Skin factor |
| Δt | Elapsed time since the reference time (original perforation allowing fluid influx), hr |
| ϕ | Porosity, fraction |
| η | Hydraulic diffusivity, md-psia/cp |
| μ | Viscosity of fluid, cp |

### (a) Computation of Pressure

The wellbore flowing pressure in the Laplace domain can be expressed as:

$${\overline{p}}_{w f} = \frac{\frac{{p}_{0}}{l} - \frac{24 {K}_{0} ( γ ) \{ \begin{matrix}{C}_{1} ( {p}_{w f 1} - {p}_{w f 0} ) + {C}_{2} ( {p}_{w f 2} - {p}_{w f 1} ) + \\ {C}_{3} ( {p}_{w f 3} - {p}_{w f 2} ) + … - {C}_{n} {p}_{w f n - 1}\end{matrix} \}}{αβ {K}_{1} ( β )}}{1 + \frac{24 l {C}_{n} {K}_{0} ( γ )}{α β {K}_{1} ( β )}} \qquad Eq . ( 1 )$$

As Eq. (1) presents the transformed wellbore flowing pressure in the Laplace domain (p̅_{wf}), inversion into the time domain for computing the wellbore flowing pressure results in:

p_{wf}(Δt)=L⁻¹(p̅_{wf}) Eq. (2)

Eq. (2) shows how the wellbore flowing pressure in the Laplace domain (p̅_{wf}) from Eq. (1) is utilized in calculating the corresponding wellbore flowing pressure. Note that operator L represents the Laplace transform, and operator L⁻¹ represents the inverse Laplace transform. For example, the inverse operation of the Laplace transform may be accomplished with the Stehfest algorithm (1970).

The parameters in Eq. (1) can be expanded as shown below.

$$η = \frac{2.637 e - 4 k}{ϕμ {c}_{t}} \qquad Eq . ( 3 )$$

$$α = \frac{k h}{141.2 μ} \qquad Eq . ( 4 )$$

$$γ = {r}_{w a} \sqrt{l / η} \qquad Eq . ( 5 )$$

$$β = {r}_{w} \sqrt{l / η} \qquad Eq . ( 6 )$$

The late-time pressure behavior can be derived from Eq. (1) and Eq. (2) as:

$${p}_{wf} {\vert}_{Late} = {p}_{0} - \frac{( 24 ) ( 141.2 )}{2 kh Δ t / u} \times [ {C}_{1} ( {p}_{wf 1} - {p}_{wf 0} ) + {C}_{2} ( {p}_{wf 2} - {p}_{wf 1} ) + \text{} … + {C}_{n - 1} ( {p}_{wfn - 1} - {p}_{wfn - 2} ) + {C}_{n} ( p0 - {p}_{wfn - 1} ) ] \qquad Eq . ( 7 )$$

Eq. (7) is used to ascertain the infinite-acting radial flow with sufficient data gathered during the test. In particular, Eq. (7) shows how the late-time pressures are related to reservoir parameters.

### (b) Computation of Influx Rate

The influx rate in the Laplace domain during the n^{th} storage sequence can be expressed as:

q̅=24Cₙ(lp̅_{wf}−p_{wfn-1})/B Eq. (8)

The influx rate at standard conditions can be obtained by employing the Stehfest algorithm for inverting q̅ from Eq. (8) as shown below:

q(Δt)=L⁻¹(q̅) Eq. (9)

### (c) Computation of Impulse Derivative

In contrast to the traditional well test derivative, the impulse derivative is utilized to ascertain if the infinite-acting radial flow has been achieved. The impulse derivative can be calculated as below:

$$I ( Δ t ) = {( Δ t )}^{2} \frac{d {p}_{w f}}{d Δ t} = {( Δ t )}^{2} {L}^{- 1} \{ L ( \frac{d {p}_{w f}}{d Δ t} ) \} = {( Δt )}^{2} {L}^{- 1} \{ ( l {\overline{p}}_{w f} - {p}_{0} ) \} {( Δ t )}^{2} {L}^{- 1} \{ ( l {\overline{p}}_{w f} ) \} {( Δ t )}^{2} {p}_{0} δ ( Δ t - 0 ) = {( Δ t )}^{2} {L}^{- 1} \{ ( l {\overline{p}}_{w f} ) \} \qquad Eq . ( 10 )$$

Eq. (10) shows how the wellbore flowing pressure in the Laplace domain (p̅_{wf}) from Eq. (1) is utilized in calculating the corresponding impulse derivative. Stabilized value of the impulse derivative on establishing the infinite-acting radial flow can be found by carrying out mathematical operations on the late-time pressure behavior of Eq. (7) with the definition of impulse derivative in Eq. (10). The magnitude of the stabilized impulse derivative during the n^{th} storage sequence can be expressed as:

$${I}_{s t a b} = {( Δ t )}^{2} \frac{d {p}_{w f}}{d Δ t} = \frac{( 24 ) ( 141.2 )}{\frac{2 k h}{μ}} [ {C}_{1} ( {p}_{wf 1} - {p}_{wf 0} ) + ( {C}_{2} ( {p}_{wf 2} - {p}_{wf 1} ) + … + {C}_{n - 1} ( {p}_{wfn - 1} - {p}_{wfn - 2} ) + {C}_{n} ( {p}_{0} - {p}_{wfn - 1} ) ] \qquad ( 24 )$$

Although Eq. (10) suggests that the impulse derivative is a function of the elapsed time, Eq. (11) shows that the impulse derivative at the late times becomes independent of elapsed time. Note the magnitude of I_{stab} relates wellbore storage and terminal pressure values at the wellbore with the reservoir properties. Therefore, Eq. (11) can be utilized in estimating reservoir transmissibility, flow capacity and permeability, and to indicate how long the test needs to run for making sure that the data contains the reservoir information. A minimum test duration to capture sufficient data can be predicted by evaluating the impulse derivative on the log-log plot of impulse derivative.

The pressure data captured over a sufficient test duration contain reliable reservoir information at the late times of the test duration. Two diagnostic plots are described below for determining if sufficient data have been captured for extracting reservoir properties, such as reservoir transmissibility, flow capacity or permeability and initial reservoir pressure. The first diagnostic plot is based on Eq. (7), which indicates that wellbore pressure versus inverse of the elapsed time (p_{wf} versus 1/Δt) at the late times approaches a straight line. The slope of this straight line provides reservoir properties and the intercept at the zero abscissa (i.e., X-coordinate) corresponds to the initial reservoir pressure. The second diagnostic plot is plotting the impulse derivative versus the elapsed time on a log-log plot (I versus Δt) according to Eq. (10), which results in a stabilized value (i.e., independent of time) of impulse derivative at the late times as indicated by Eq. (11). The stabilized value of the impulse derivative provides the reservoir properties. The first and second diagnostic plots provide dual confirmation that validates the data sufficiency for extracting approximate reservoir parameters.

The process of plotting and analyzing the data described above is referred to as the multiple-storage phenomenon analysis step. The reservoir parameters estimated in the multiple-storage phenomenon analysis step is approximate and is refined through the multiple-storage phenomenon modeling step described below.

In the multiple-storage phenomenon analysis step, approximate reservoir parameters are extracted from the analysis of the two diagnostic plots. In analyzing the first diagnostic plot, the best-fit straight line is determined by a regression technique. FIG. 3B shows an example first diagnostic plot (320) with a straight line (321) fitting through the wellbore pressure data points at the very late end of the test period (i.e., as the inverse time 1/Δt approaches zero). The wellbore pressure data points correspond to the wellbore pressure profile (311) shown in FIG. 3A. The vertical intercept of this extrapolated straight line (321) at (1/Δt)=0 provides the initial reservoir pressure, and the slope (m) of the extrapolated straight line (321) provides the reservoir transmissibility (kh/μ) according to Eq. (7) above. Specifically, substituting (1/Δt)=0 in Eq, (7) results in Eq, (12) and Eq. (13) below.

$${p}_{w f} {\vert}_{( 1 / Δ t ) = 0} = {p}_{0} \qquad Eq . ( 12 )$$

$$\frac{k h}{μ} = - \frac{( 24 ) ( 141.2 )}{2 m} [ {C}_{1} ( {p}_{wf 1} - {p}_{wf 0} ) + {C}_{2} ( {p}_{wf 2} - {p}_{wf 1} ) + … + {C}_{n - 1} ( {p}_{wfn - 1} - {p}_{wfn - 2} ) + {C}_{n} ( {p}_{0} - {p}_{wfn - 1} ) ] \qquad Eq . ( 13 )$$

FIG. 3C shows an example second diagnostic plot (330) of plotting impulse derivative (331) and influx rate (332) versus time. In addition, wellbore pressure data points are optionally plotted that correspond to the wellbore pressure profile (311) shown in FIG. 3A. As shown in FIG. 3C, the impulse derivative (331) appears to have stabilized at I_{stab}=14,240 psia-hr during the late time period (333) with the wellbore storage regime of C₄. Accordingly, the late part of the data corresponding to C₄ can be utilized to extract the reservoir transmissibility. Specifically, rearranging Eq, (11) results in Eq, (14) below.

$$\frac{k h}{μ} = \frac{( 24 ) ( 141.2 )}{2 {I}_{s t a b}} [ {C}_{1} ( {p}_{wf 1} - {p}_{wf 0} ) + {C}_{2} ( {p}_{wf 2} - {p}_{wf 1} ) + … + {C}_{n - 1} ( {p}_{wfn - 1} - {p}_{wfn - 2} ) + {C}_{n} ( {p}_{0} - {p}_{wfn - 1} ) ] \qquad Eq . ( 14 )$$

The example shown in FIGS. 3A-3C is described below in the context of the multiple-storage phenomenon analysis listed in TABLE 2. Specifically, TABLE 2 lists the workflow steps of the multiple-storage phenomenon analysis to generate approximate reservoir parameters.

Table 2: Multiple-storage Phenomenon Analysis Steps
Select a time range in the captured data.
Obtain, or otherwise derive, measured well pressure from the selected time range of the captured data.
Identify the wellbore fluids based on open hole logs or other sources.
Retrieve rock, fluid, and petrophysical properties of the reservoir and identified fluids from a database.
Determine the number of wellbore storage constants corresponding to the selected time range based on a sequence of transient pressure progressions identified in the selected time range.
Record the terminal wellbore pressures p_{wf0}, p_{wf1}, p_{wf2}, p_{wf3}, . . . , p_{wfn-1}.
Estimate the chamber volumes and respective wellbore storage constants based on well schematics and sequence of events in the drill stem tests.
Construct the first and second diagnostic plots.
Determine if the captured data in the time range is sufficient for deriving reliable reservoir parameters.
Generate estimated reservoir parameters from the diagnostic plots as inputs to the multiple-storage phenomenon modeling step.

As shown in FIG. 3A, there are four wellbore storage constants in a time sequence (n=4). To confirm a drill stem test time period for capturing sufficient amount of data to generate reliable reservoir parameters estimation, the late time pressure data on the p_{wf} versus 1/Δt plot in FIG. 3B is fitted on a straight line (321). For example, the line fitting may be performed using a mathematical linear regression method over a pre-determined time period (i.e., the late time period) in FIG. 3B, such as 500 hr-1,000 hr corresponding to 0.001-0.002 in inverse time. Alternatively, the time period 600 hr-1,000 hr corresponding to C₄ shown in FIG. 3A may be used as the late time period. The regression error is then used as a measure of data sufficiency. Note that FIG. 3B includes no captured pressure data points in the time period beyond 1,000 hr (i.e., corresponding to 0-0.001 in inverse time) where the straight line (321) extrapolates the captured pressure data points to intercept the 0 abscissa (i.e., X-coordinate) at 2,300 psia. Accordingly, the initial reservoir pressure is estimated from the captured wellbore pressure data as 2,300 psia.

The data sufficiency is further confirmed on the log-log plot of I versus Δt in FIG. 3C by detecting the flattening of impulse derivative for a stabilized value I_{stab}. For example, the plot flattening may be detected using a mathematical linear regression method over a predetermined time period (i.e., the late time period) in FIG. 3C, such as from 500 hr-1,000 hr. The regression error is then used as an additional measure of data sufficiency.

The estimated reservoir parameters generate from the multiple-storage phenomenon analysis are summarized in TABLE 3 below. In particular, Eq. (12) through Eq. (14) are used to estimate the reservoir parameters. For comparison purpose, known reservoir parameters are listed as the base reservoir parameters in column 5 of TABLE 3. As expected, the impulse derivative approach (i.e., the second diagnostic plot) has resulted in a closer transmissibility value of 0.2827 md-ft/cp in column 7 to the base transmissibility of 0.2836 md-ft/cp than the late-time pressure approach (i.e., the first diagnostic plot) has resulted in the value of 0.2789 md-ft/cp in column 6. Note that the impulse derivative approach uses an estimate of the initial reservoir pressure as input to Eq. (14). The estimated initial reservoir pressure in Eq. (12) of the late-time pressure approach is used to complement the impulse derivative approach as an input parameter to Eq. (10) and Eq. (11) in calculating the impulse derivative. In addition, this first estimate of the initial reservoir pressure is used as input to Eq. (1), Eq. (10), Eq. (11) and Eq. (14) in the subsequent multiple-storage phenomenon modeling.

TABLE 3
Summary of Analysis Parameters

| | | | | | | Output of I |
|---|---|---|---|---|---|---|
| | | | | | Output of | versus Δt |
| | | Wellbore | Terminal | | p_{wƒ} versus | log-log |
| | Identified | Storage | Wellbore | Base | 1/Δt First | Second |
| | Periods, | Constants, | Pressures, | Reservoir | Diagnostic | Diagnostic |
| n | hr | bbl/psia | psia | Parameters | Plot | Plot |
| 4 | Period = | C₁ = | p_{wƒ0} = | p₀ = 2,300 | p₀ = 2,300 | I_{stab} = |
| | 100 | 0.001279 | 234.9 | psia | psia | 14,240 |
| | | | | | | psia-hr |
| | Period = | C₂ = | p_{wƒ1} = | kh | m = | kh |
| | 200 | 0.000791 | 1,803.92 | μ = 0.2836 | −14,427 | μ = 0.2827 |
| | | | | md-ft/cp | psia-hr | md-ft/cp |
| | Period = | C₃ = | p_{wƒ2} = | | kh | |
| | 300 | 0.000569 | 2,230.26 | | μ = 0.2789 | |
| | Period = | C₄ = | p_{wƒ3} = | | md-ft/cp | |
| | 400 | 0.000253 | 2,273.18 | | | |

The estimated reservoir parameters generated from the multiple-storage phenomenon analysis above are further refined by performing the multiple-storage phenomenon modeling of the entire pressure data in the drill stem test duration. The multiple-storage phenomenon modeling is to calibrate and refine the reservoir parameters for matching all the data captured over the test duration with the model responses. In particular, the model responses are computed using Eq. (2), Eq. (9), and Eq. (10) above. TABLE 4 lists the workflow steps of modeling the test data.

Table 4: Multiple-storage Phenomenon Modeling Steps
Select a time range in the captured data.
Construct the first and second diagnostic plots.
Retrieve rock, fluid, and petrophysical properties of the reservoir and identified fluids from a database.
Obtain estimated wellbore storage constants, terminal wellbore pressures, and reservoir properties from the multiple-storage phenomenon analysis step.
Calculate model responses using Eq. (2), Eq. (9), and Eq. (10), which collectively form the multiple-storage phenomenon model.
Compare the model responses (e.g., modeled wellbore pressure) to test data (e.g., captured wellbore pressure) on the first and second diagnostic plots.
Adjust wellbore storage constants and reservoir parameters to reduce the comparison differences between the model responses and test data.
Generate and report final reservoir parameters and influx rate profile.

The multiple-storage phenomenon modeling allows either a human analyst or a computer matching algorithm to make sure that the reservoir parameters are consistent over the entire test duration by matching the model responses with the test data. In the process of matching, the terminal wellbore pressures (p_{wf0}, p_{wf1}, p_{wf2}, p_{wf3}, . . . , p_{wfn-1}) are not normally adjusted as these are the measured pressure values. Permeability, flow capacity or transmissibility, initial reservoir pressure, skin factor and wellbore storage constants are the target parameters for adjustments in obtaining a match. While matching the model responses with the test data, the analyst or the computer matching algorithm emphasizes (i.e., assigns higher weightings to) the late-time data because the late-time data tends to convey reservoir signals through the transient-pressure data.

To compare the measured pressure and the impulse derivative values of the test data to the respective values generated from the model, a set of estimated values of select parameters (e.g., wellbore storage constants C₁, C₂, C₃, . . . , Cₙ, reservoir permeability k, and skin factor s) on the diagnostics plots are utilized. Matching or comparing respective values from an actual test and the model is performed based on pre-specified criteria. For example, an example criterion may include minimizing the standard deviation of the differences between the measured and the model pressure values. The example criterion may include minimizing the standard deviation in the linear plots of [p_{wf} versus Δt] and [p_{wf} versus 1/Δt], and the log-log plot of [I versus Δt]. Since there are no actual measurements of influx rates, these are overlaid on the [p_{wf} versus Δt] plot as model output.

To perform the multiple-storage phenomenon modeling, estimated reservoir properties from the multiple-storage phenomenon analysis and some other rock and fluid properties are used as inputs to the model (i.e., Eq. (2), Eq. (9), and Eq. (10)). For example, the base parameters in TABLE 5 are used as inputs to the model. When an acceptable match has been obtained, the calibrated parameters are accepted as the output of the model. For example, the model output transmissibility of 0.2838 md-ft/cp is obtained which is the same as the base reservoir parameter.

FIGS. 3D-3F show the match of the model responses with the test data. In particular, FIG. 3D shows the modeled wellbore pressure versus time [p_{wf} versus Δt] as the solid line curve (341) overlaid on top of the wellbore pressure (311) shown in FIG. 3A. FIG. 3E shows the modeled wellbore pressure versus inverse time [p_{wf} versus 1/Δt] as the solid line curve (351) overlaid on top of the first diagnostic plot shown in FIG. 3B. FIG. 3F shows the modeled impulse derivative versus inverse time [I versus Δt] as the solid line curve (361) overlaid on top of the second diagnostic plot shown in FIG. 3C.

TABLE 5 presents the model input (base parameters) and output of the example described in reference to FIGS. 3A-3C above.

TABLE 5
Comparison of Base Parameters to Model Output

| Base Parameters | Model Output |
|---|---|
| p₀ = 2,300 psia | p₀ = 2,300 psia |
| p_{wf0} = 234.9 psia | |
| k = 0.0432 md h = 4.757 ft B = 1.003 bbl/STB μ = 0.7246 cp | $\begin{matrix}\frac{kh}{μ} = 0.2836 \\ md - ft / cp\end{matrix}$ |
| ϕ = 0.15 | |
| cₜ = 3.2884 e − 5/psia | |
| r_{w} = 0.3 ft | |
| $\begin{matrix}\frac{kh}{μ} = 0.2836 \\ md - ft / cp\end{matrix}$ | |
| s = 0 | s = 0 |
| n = 4 | n = 4 |
| p_{wf0} = 234.9 psia | p_{wf0} = 234.9 psia |
| p_{wf1} = 1,803.92 psia | p_{wf1} = 1,803.92 psia |
| p_{wf2} = 2,230.26 psia | p_{wf2} = 2,230.26 psia |
| p_{wf3} = 2,273.18 psia | p_{wf3} = 2,273.18 psia |
| C₁ = 0.001279 bbl/psia | C₁ = 0.001279 bbl/psia |
| C₂ = 0.000791 bbl/psia | C₂ = 0.000791 bbl/psia |
| C₃ = 0.000569 bbl/psia | C₃ = 0.000569 bbl/psia |
| C₄ = 0.000253 bbl/psia | C₄ = 0.000253 bbl/psia |

Embodiments may be implemented on a computing system. Any combination of mobile, desktop, server, router, switch, embedded device, or other types of hardware may be used. For example, as shown in FIG. 4A, the computing system (400) may include one or more computer processors (402), non-persistent storage (404) (e.g., volatile memory, such as random access memory (RAM), cache memory), persistent storage (406) (e.g., a hard disk, an optical drive such as a compact disk (CD) drive or digital versatile disk (DVD) drive, a flash memory, etc.), a communication interface (412) (e.g., Bluetooth interface, infrared interface, network interface, optical interface, etc.), and numerous other elements and functionalities.

The computer processor(s) (402) may be an integrated circuit for processing instructions. For example, the computer processor(s) may be one or more cores or micro-cores of a processor. The computing system (400) may also include one or more input devices (410), such as a touchscreen, keyboard, mouse, microphone, touchpad, electronic pen, or any other type of input device.

The communication interface (412) may include an integrated circuit for connecting the computing system (400) to a network (not shown) (e.g., a local area network (LAN), a wide area network (WAN) such as the Internet, mobile network, or any other type of network) and/or to another device, such as another computing device.

Further, the computing system (400) may include one or more output devices (408), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (402), non-persistent storage (404), and persistent storage (406). Many different types of computing systems exist, and the aforementioned input and output device(s) may take other forms.

Software instructions in the form of computer readable program code to perform embodiments of the disclosure may be stored, in whole or in part, temporarily or permanently, on a non-transitory computer readable medium such as a CD, DVD, storage device, a diskette, a tape, flash memory, physical memory, or any other computer readable storage medium. Specifically, the software instructions may correspond to computer readable program code that, when executed by a processor(s), is configured to perform one or more embodiments of the disclosure.

The computing system (400) in FIG. 4A may be connected to or be a part of a network. For example, as shown in FIG. 4B, the network (420) may include multiple nodes (e.g., node X (422), node Y (424)). Each node may correspond to a computing system, such as the computing system shown in FIG. 4A, or a group of nodes combined may correspond to the computing system shown in FIG. 4A. By way of an example, embodiments of the disclosure may be implemented on a node of a distributed system that is connected to other nodes. By way of another example, embodiments of the disclosure may be implemented on a distributed computing system having multiple nodes, where each portion of the disclosure may be located on a different node within the distributed computing system. Further, one or more elements of the aforementioned computing system (400) may be located at a remote location and connected to the other elements over a network.

Although not shown in FIG. 4B, the node may correspond to a blade in a server chassis that is connected to other nodes via a backplane. By way of another example, the node may correspond to a server in a data center. By way of another example, the node may correspond to a computer processor or micro-core of a computer processor with shared memory and/or resources.

The nodes (for example, node X (422), node Y (424)) in the network (420) may be configured to provide services for a client device (426). For example, the nodes may be part of a cloud computing system. The nodes may include functionality to receive requests from the client device (426) and transmit responses to the client device (426). The client device (426) may be a computing system, such as the computing system shown in FIG. 4A. Further, the client device (426) may include or perform all or a portion of one or more embodiments of the disclosure.

While the disclosure has been described with respect to a limited number of embodiments, those skilled in the art, having benefit of this disclosure, will appreciate that other embodiments can be devised which do not depart from the scope of the disclosure as disclosed herein. Accordingly, the scope of the disclosure should be limited only by the attached claims.

What is claimed is:

1. A method of estimating reservoir properties, comprising:
obtaining downhole pressure data during a drill stem test in a wellbore penetrating a reservoir;
computing a first linearity measure of a first diagnostic plot, wherein the first diagnostic plot represents a first dependency of the downhole pressure data on a linear-scale with respect to inverse time on a linear-scale;
determining, based at least on the first linearity measure, data sufficiency of the drill stem test; and
generating, from the downhole pressure data and based at least on the data sufficiency, an estimation of the reservoir properties.

2. The method of claim 1,
wherein the drill stem test comprises a multiple-storage phenomenon with no production fluid flow at surface,
wherein the downhole pressure data comprises a plurality of terminal wellbore pressures of the multiple-storage phenomenon, and
wherein the estimation of the reservoir properties comprises an estimated initial wellbore pressure, a stabilized value of an impulse derivative of the downhole pressure data, an estimated reservoir transmissibility, and a plurality of estimated wellbore storage constants corresponding to the plurality of terminal wellbore pressures.

3. The method of claim 1, further comprising:
computing a second linearity measure of a second diagnostic plot, wherein the second diagnostic plot represents a second dependency of an impulse derivative of the downhole pressure data on the log-scale with respect to time on the log-scale,
wherein determining the data sufficiency is further based on the second linearity measure.

4. The method of claim 1, further comprising:
continuing the drill stem test until at least the data sufficiency satisfies a pre-determined criterion.

5. The method of claim 1,
wherein the first linearity measure comprises a linear regression error of the downhole pressure data with respect to a first straight line on the first diagnostic plot, and
wherein generating the estimation of the reservoir properties is based at least on a slope and an abscissa intercept of the first straight line.

6. The method of claim 2,
wherein the second linearity measure comprises a linear regression error of the downhole pressure data with respect to a second straight line on the second diagnostic plot,
wherein the second straight line corresponds to a stabilized value of the impulse derivative, and
wherein generating the estimation of the reservoir properties is based at least on the stabilized value of the impulse derivative.

7. The method of claim 1, further comprising:
generating, using the estimation of reservoir properties as input to a multiple-storage phenomenon model, a sequence of modeled wellbore pressure, and
generating final reservoir parameters by adjusting the estimation of reservoir properties to match the sequence of modeled wellbore pressure and the downhole pressure data.

8. A system for estimating reservoir properties, the system comprising:
a memory; and
a computer processor connected to the memory and that:
obtains downhole pressure data during a drill stem test in a wellbore penetrating a reservoir;
computes a first linearity measure of a first diagnostic plot, wherein the first diagnostic plot represents a first dependency of the downhole pressure data on a linear-scale with respect to inverse time on a linear-scale;
determines, based at least on the first linearity measure, data sufficiency of the drill stem test; and
generates, from the downhole pressure data and based at least on the data sufficiency, an estimation of the reservoir properties.

9. The system of claim 8,
wherein the drill stem test comprises a multiple-storage phenomenon with no production fluid flow at surface,
wherein the downhole pressure data comprises a plurality of terminal wellbore pressures of the multiple-storage phenomenon, and
wherein the estimation of the reservoir properties comprises an estimated initial wellbore pressure, a stabilized value of an impulse derivative of the downhole pressure data, an estimated reservoir transmissibility, and a plurality of estimated wellbore storage constants corresponding to the plurality of terminal wellbore pressures.

10. The system of claim 8, the computer processor further:
computes a second linearity measure of a second diagnostic plot, wherein the second diagnostic plot represents a second dependency of an impulse derivative of the downhole pressure data on the log-scale with respect to time on the log-scale,
wherein determining the data sufficiency is further based on the second linearity measure.

11. The system of claim 8, the computer processor further:
continues the drill stem test until at least the data sufficiency satisfies a pre-determined criterion.

12. The system of claim 8,
wherein the first linearity measure comprises a linear regression error of the downhole pressure data with respect to a first straight line on the first diagnostic plot, and
wherein generating the estimation of the reservoir properties is based at least on a slope and an abscissa intercept of the first straight line.

13. The system of claim 9,
wherein the second linearity measure comprises a linear regression error of the downhole pressure data with respect to a second straight line on the second diagnostic plot,
wherein the second straight line corresponds to a stabilized value of the impulse derivative, and
wherein generating the estimation of the reservoir properties is based at least on the stabilized value of the impulse derivative.

14. The system of claim 8, the computer processor further:
generates, using the estimation of reservoir properties as input to a multiple-storage phenomenon model, a sequence of modeled wellbore pressure, and
generates final reservoir parameters by adjusting the estimation of reservoir properties to match the sequence of modeled wellbore pressure and the downhole pressure data.

15. A non-transitory computer readable medium (CRM) storing computer readable program code for estimating reservoir properties, wherein the computer readable program code, when executed by a computer, comprises functionality for:
obtaining downhole pressure data during a drill stem test in a wellbore penetrating a reservoir;
computing a first linearity measure of a first diagnostic plot, wherein the first diagnostic plot represents a first dependency of the downhole pressure data on a linear-scale with respect to inverse time on a linear-scale;
determining, based at least on the first linearity measure, data sufficiency of the drill stem test; and
generating, from the downhole pressure data and based at least on the data sufficiency, an estimation of the reservoir properties.

16. The non-transitory CRM of claim 15,
wherein the drill stem test comprises a multiple-storage phenomenon with no production fluid flow at surface,
wherein the downhole pressure data comprises a plurality of terminal wellbore pressures of the multiple-storage phenomenon, and
wherein the estimation of the reservoir properties comprises an estimated initial wellbore pressure, a stabilized value of an impulse derivative of the downhole pressure data, an estimated reservoir transmissibility, and a plurality of estimated wellbore storage constants corresponding to the plurality of terminal wellbore pressures.

17. The non-transitory CRM of claim 15, the computer readable program code, when executed by the computer, further comprising functionality for:
computing a second linearity measure of a second diagnostic plot, wherein the second diagnostic plot represents a second dependency of an impulse derivative of the downhole pressure data on the log-scale with respect to time on the log-scale,
wherein determining the data sufficiency is further based on the second linearity measure.

18. The non-transitory CRM of claim 15, the computer readable program code, when executed by the computer, further comprising functionality for:
continuing the drill stem test until at least the data sufficiency satisfies a pre-determined criterion.

19. The non-transitory CRM of claim 16,
wherein the first linearity measure comprises a linear regression error of the downhole pressure data with respect to a first straight line on the first diagnostic plot,
wherein the second linearity measure comprises a linear regression error of the downhole pressure data with respect to a second straight line on the second diagnostic plot,
wherein the second straight line corresponds to a stabilized value of the impulse derivative, and
wherein generating the estimation of the reservoir properties is based at least on a slope and an abscissa intercept of the first straight line and the stabilized value of the impulse derivative.

20. The non-transitory CRM of claim 15, the computer readable program code, when executed by the computer, further comprising functionality for:
generating, using the estimation of reservoir properties as input to a multiple-storage phenomenon model, a sequence of modeled wellbore pressure, and
generating final reservoir parameters by adjusting the estimation of reservoir properties to match the sequence of modeled wellbore pressure and the downhole pressure data.
